(19) United States
(12) Patent Application Publication
(10) Pub. No.: US 2025/0048619 A1
(43) Pub. Date: Feb. 6, 2025

(54) SEMICONDUCTOR DEVICE AND METHOD FOR FABRICATING THE SAME

(71) Applicant: Samsung Electronics Co., Ltd., Suwon-si (KR)

(72) Inventors: Yoongoo KANG, Suwon-si (KR); Dongyoung KIM, Suwon-si (KR); Jaehong PARK, Suwon-si (KR); Seokjae WON, Suwon-si (KR)

(73) Assignee: Samsung Electronics Co., Ltd., Suwon-si (KR)

(21) Appl. No.: 18/421,113

(22) Filed: Jan. 24, 2024

(30) Foreign Application Priority Data
Aug. 2, 2023 (KR) 10-2023-0101036

(51) Int. Cl. H10B 12/00; H01L 23/528

(52) U.S. Cl. CPC H10B 12/482; H01L 23/528; H10B 12/0335; H10B 12/488

(57) ABSTRACT

The present inventive concepts relate to semiconductor devices and methods for fabricating the same, and a semiconductor device according to some example embodiments includes: a substrate including an active region defined by a device isolation layer; a word line that crosses and overlaps the active region; a bit line crossing the active region in a direction different from the word line; a direct contact that connects the active region and the bit line and includes a metallic material; a buried contact connected to the active region; and a bit line spacer between the bit line and the buried contact, wherein a width of the direct contact is different from that of the bit line, and the bit line spacer is on an upper surface of the direct contact.

### CROSS-REFERENCE TO RELATED APPLICATION

This application claims priority to and the benefit of Korean Patent Application No. 10-2023-0101036 filed in the Korean Intellectual Property Office on Aug. 2, 2023, the entire contents of which are incorporated herein by reference.

### BACKGROUND

### 1. Field

The present inventive concepts relate to semiconductor devices and methods for fabricating the same.

### 2. Description of the Related Art

As semiconductor devices become increasingly highly integrated, individual circuit patterns are becoming more refined in order to implement more semiconductor devices in the same area. That is, as the degree of integration of semiconductor devices increases, design rules for constituent elements of the semiconductor devices decrease.

In highly scaled semiconductor devices, a process of forming a plurality of bit lines and direct contacts connected thereto is becoming increasingly complicated and difficult.

### SUMMARY

Some example embodiments provide a semiconductor device with improved reliability and productivity and/or a method for fabricating the same.

Some example embodiments provide a semiconductor device that may include: a substrate including an active region defined by a device isolation layer; a word line that crosses and overlaps the active region; a bit line crossing the active region in a direction different from the word line; a direct contact that connects the active region and the bit line and includes a metallic material; a buried contact connected to the active region; and a bit line spacer disposed between the bit line and the buried contact. A width of the direct contact may be different from the width of the bit line, and the bit line spacer may be on an upper surface of the direct contact.

Some example embodiments provide a semiconductor device that may include: a substrate including an active region defined by a device isolation layer; a word line that crosses and overlaps the active region; a bit line crossing the active region in a direction different from the word line; a direct contact that connects the active region and the bit line and includes a metallic material; a silicide layer between the active region and the direct contact; a buried contact connected to the active region; a first bit line spacer on an upper surface of the direct contact; a second bit line spacer between the first bit line spacer and the buried contact; and a landing pad connected to the active region through the buried contact, wherein a width of the direct contact is greater than a width of the bit line.

Some example embodiments provide a fabricating method of a semiconductor device, where the method may include: forming a device isolation layer in a substrate to define an active region; forming an insulating layer on the substrate and then patterning the insulating layer to form a direct contact trench to expose an upper surface of the active region; forming a trench spacer in the direct contact trench on the exposed upper surface of the active region; forming a first material layer including a metallic material in the direct contact trench; sequentially stacking a second material layer, a third material layer, and a fourth material layer on the insulating layer and the first material layer; forming a bit line based on patterning at least some of the second material layer, the third material layer, and the fourth material layer; forming a first bit line spacer to cover a side surface of the bit line; patterning the trench spacer and the first material layer using the first bit line spacer as an etching mask, forming a direct contact connected to the active region and the bit line; forming a second bit line spacer covering the first bit line and the direct contact; forming a buried contact connected to the active region; and forming a landing pad connected to the active region through the buried contact.

According to some example embodiments, as a bit line spacer including a low dielectric material is disposed on a side surface of a bit line, a semiconductor device having improved electrical characteristics may be provided.

### BRIEF DESCRIPTION OF THE DRAWINGS

FIG. 1 illustrates a top plan view of a semiconductor device according to some example embodiments.

FIG. 2 illustrates a cross-sectional view taken along line I-I′ of FIG. 1.

FIG. 3 illustrates a cross-sectional view taken along line II-II′ of FIG. 1.

FIG. 4 illustrates a partially enlarged view of region R1 of FIG. 2 according to some example embodiments.

FIGS. 5, 6, and 7 illustrate partial enlarged views of cross-sections of a semiconductor device according to some example embodiments.

FIGS. 8, 9, 10, 11, 12, 13, 14, 15, 16, 17, 18, 19, and 20 illustrate cross-sectional views for explaining a method for fabricating a semiconductor device according to some example embodiments.

### DETAILED DESCRIPTION

The present inventive concepts will be described more fully hereinafter with reference to the accompanying drawings, in which some example embodiments of the inventive concepts are shown. As those skilled in the art would realize, the described example embodiments may be modified in various different ways, all without departing from the spirit or scope of the present inventive concepts.

In order to clearly describe the present inventive concepts, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present inventive concepts are not necessarily limited to those illustrated in the drawings. In the drawings, the thicknesses of layers, films, panels, regions, areas, etc., are exaggerated for clarity. In the drawings, for ease of description, the thicknesses of some layers, regions, and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal,” or “identical” may be used in description of some example embodiments, it should be understood that some imprecisions may exist. Thus, when a first element, property, or value is referred to as being “the same as,” “equal to,” or “identical to” a second element, property, or value, and regardless of whether the first element, property, or value is modified as “substantially” the same as, equal to, or identical to the second element, property, or value, it should be understood that the first element, property, or value is “the same as,” “equal to” or “identical to” the second element, property, or value within a desired manufacturing or operational tolerance range (e.g., ±10%).

It will be understood that elements and/or properties thereof described herein as being “substantially” the same, equal, and/or identical, encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

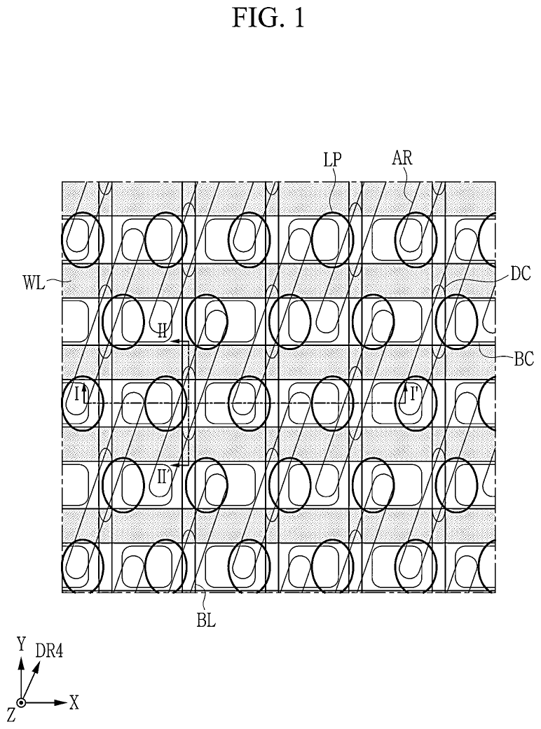

Hereinafter, a semiconductor device according to some example embodiments will be described with reference to FIG. 1 to FIG. 3.

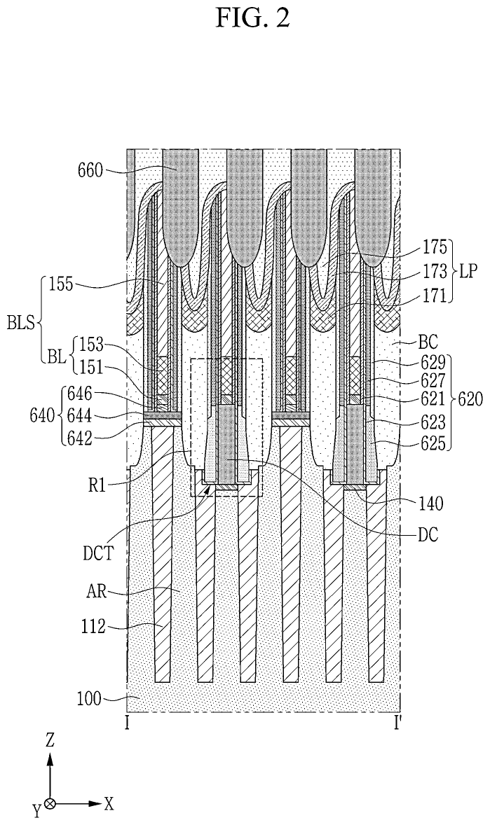

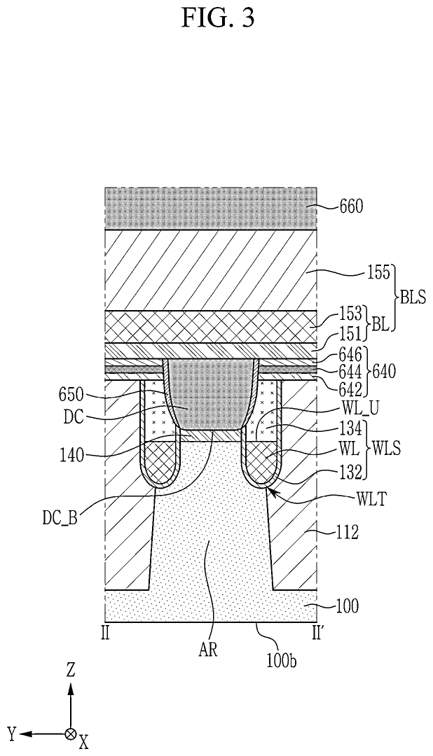

FIG. 1 illustrates a top plan view of a semiconductor device according to some example embodiments. FIG. 2 illustrates a cross-sectional view taken along line I-I′ of FIG. 1. FIG. 3 illustrates a cross-sectional view taken along line II-II′ of FIG. 1.

Referring to FIG. 1 to FIG. 3, a semiconductor device according to some example embodiments may include an active region AR, a word line WL crossing and overlapping the active region AR, a bit line BL crossing and overlapping the active region AR in a direction different from that of the word line WL, a direct contact DC connecting the active region AR and the bit line BL, a buried contact BC connected to the active region AR, and a bit line spacer structure 620 disposed between the bit line BL and the buried contact BC. The semiconductor device according to some example embodiments may further include a landing pad LP connected to the buried contact BC. The buried contact BC may connect the active region AR and the landing pad LP.

A substrate 100 may include a cell array region and a peripheral circuit region. A cell array region is a region in which a plurality of memory cells are formed, and a plurality of active regions AR may be disposed in the cell array region. The peripheral circuit region may be disposed to surround the cell array region, and elements driving memory cells may be disposed therein. FIG. 1 to FIG. 3 illustrate the cell array region for convenience, and the illustration of the peripheral circuit region is omitted.

The active region AR may be defined by a device isolation layer 112 disposed within the substrate 100. The plurality of active regions AR may be disposed within the substrate 100, and the plurality of active regions AR may be separated from each other by the device isolation layer 112. The device isolation layers 112 may be disposed on both sides of each active region AR.

The substrate 100 may have an upper surface parallel to a first direction X and a second direction Y, and may have a thickness parallel to a third direction Z perpendicular to the first direction X and the second direction Y.

The substrate 100 may include a semiconductor material. The substrate 100 may include a group IV semiconductor, a group III-V compound semiconductor, and a group II-VI compound semiconductor. For example, the substrate 100 may include a semiconductor such as Si or Ge, or a compound semiconductor such as SiGe, SiC, GaAs, InAs, or InP. However, the material of the substrate 100 is not limited thereto, and may be variously changed.

The active region AR may have a rod shape extending along a fourth direction DR4 oblique to the first direction X and the second direction Y. The fourth direction DR4 may be parallel to the upper surface of the substrate 100, and may be disposed on substantially the same plane as the first direction X and the second direction Y. For example, the fourth direction DR4 may form an acute angle with the first direction X and the second direction Y, respectively.

The plurality of active regions AR may extend in parallel directions to each other. The plurality of active regions AR may be disposed to be spaced apart from each other by a predetermined interval along the fourth direction DR4 and the first direction X. A central portion of one active region AR may be adjacent to an end portion of another active region AR in the first direction X. One end portion of one active region AR may be adjacent to the other end portion of another active region AR in the first direction X. However, the shape or disposition form of the active region AR is not limited thereto, and may be variously changed.

The device isolation layer 112 may have a shallow trench isolation (STI) structure having excellent device isolation characteristics. The device isolation layer 112 may include a silicon oxide, a silicon nitride, or any combination thereof. However, the material and configuration of the device isolation layer 112 are not limited thereto, and may be variously changed. For example, the device isolation layer 112 may be formed as a single layer or a multilayer.

In addition, the device isolation layer 112 may be made of a single material, or may include two or more types of insulating materials.

The semiconductor device according to some example embodiments may include a plurality of word lines WL. The plurality of word lines WL may extend along the first direction X, and may be spaced apart from each other at regular intervals along the second direction Y.

Each of the plurality of word lines WL may extend along the first direction X, and may cross the active region AR. The plurality of word lines WL may overlap the active region AR, and may serve as a gate electrode.

One word line WL may overlap (e.g., in the third direction Z) a plurality of adjacent active regions AR along the first direction X. Each of the plurality of active regions AR may cross-overlap two word lines WL. Each active region AR may be divided into three portions by two word lines WL.

Here, a central of the active region AR disposed between the two word lines WL may be a portion connected to the bit line BL, and both end portions of the active region AR disposed outside the two word lines WL may be portions connected to a capacitor (not shown). The bit line BL may be connected to the active region AR through the direct contact DC. The capacitor may be connected to the active region AR through the landing pad LP and the buried contact BC.

The substrate 100 may include a word line trench WLT, and a word line structure WLS may be disposed within the word line trench WLT. That is, the word line structure WLS may have a form embedded in the substrate 100. A portion of the word line trench WLT may be disposed on the active region AR, and another portion may be disposed on the device isolation layer 112.

The word line structure WLS may include a gate insulating layer 132, a word line WL disposed on the gate insulating layer 132, and a word line capping layer 134 disposed on the word line WL. However, the position and configuration of the word line structure WLS is not limited thereto, and may be variously changed.

The gate insulating layer 132 may be disposed within the word line trench WLT. The gate insulating layer 132 may be conformally disposed on an inner sidewall of the word line trench WLT.

The gate insulating layer 132 may include a silicon oxide, a silicon nitride, a silicon oxynitride, a high-k material with a higher dielectric constant than a silicon oxide, or any combination thereof. However, the position, shape, and material of the gate insulating layer 132 are not limited thereto, and may be variously changed.

The word line WL may be disposed on the gate insulating layer 132. Side and bottom surfaces of the word line WL may be surrounded by the gate insulating layer 132. The gate insulating layer 132 may be disposed between the word line WL and the active region AR. Accordingly, the word line WL may not directly contact the active region AR.

The word line WL may include Ti, TIN, Ta, TaN, W, WN, TiSiN, WSiN, polysilicon, or any combination thereof. However, the position, shape, and material of the word line WL are not limited thereto, and may be variously changed.

The word line capping layer 134 may be disposed on the word line WL. The word line capping layer 134 may entirely cover the upper surface of the word line WL. The lower surface of the word line capping layer 134 may contact the word line WL. A side surface of the word line capping layer 134 may be covered by the gate insulating layer 132.

The word line capping layer 134 may include a silicon oxide, a silicon nitride, a silicon oxynitride, or any combination thereof. However, the position, shape, and material of the word line capping layer 134 are not limited thereto, and may be variously changed.

The semiconductor device according to some example embodiments may include a plurality of bit lines BL.

Each of the plurality of bit lines BL may extend along the second direction Y crossing the first direction X, and may be spaced apart from each other at regular intervals along the first direction X.

Each of the plurality of bit lines BL may cross the active region AR and the word line WL. The plurality of bit lines BL may be disposed on the word line WL. In some example embodiments, a bit line BL may cross the active region AR in a direction different from the word line WL. For example, the word line WL may cross the active region AR in the first direction X and the bit line BL may cross the active region AR in the second direction Y.

One bit line BL may overlap a plurality of adjacent active regions AR (e.g., in the third direction Z) along the second direction Y. Each of the plurality of bit lines BL may be connected to the active region AR through the direct contact DC.

One bit line BL may be connected to the plurality of adjacent active regions AR along the second direction Y. Each of the plurality of active regions AR may be connected to one bit line BL. A central portion of the active region AR may be connected to the bit line BL. However, this is one example, and the connection form of the bit line BL and the active region AR may be variously changed.

The substrate 100 may include a direct contact trench DCT. The direct contact trench DCT may be disposed on the active region AR.

A trench spacer 650 may be conformally disposed on a portion of an inner sidewall of the direct contact trench DCT. The trench spacer 650 is disposed on the inner sidewall of the direct contact trench DCT overlapping the bit line BL in the third direction Z, and may be spaced apart along the second direction Y within the direct contact trench DCT.

That is, the trench spacer 650 overlaps the bit line BL of the inner sidewall of the direct contact trench DCT in the third direction Z, and may be disposed only on the inner sidewall of the direct contact trench DCT disposed on one side and the other side in the second direction Y.

In other words, the trench spacer 650 does not overlap the bit line BL in the third direction Z, and may not be disposed on the inner sidewall of the direct contact trench DCT disposed on one side and the other side in the first direction X.

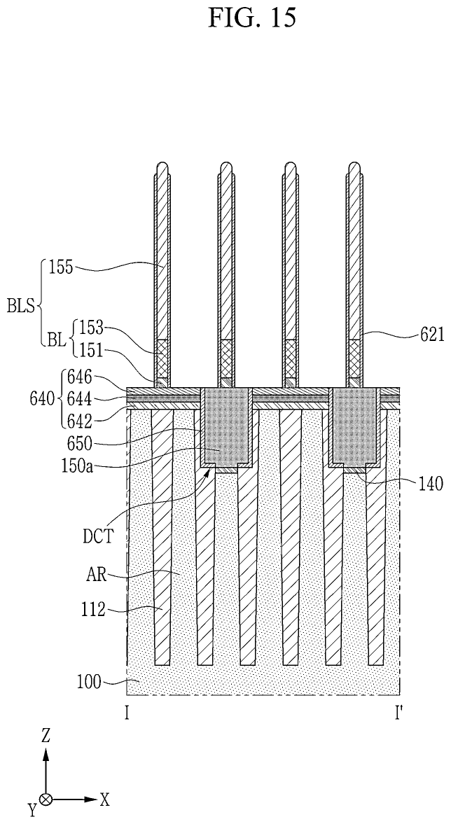

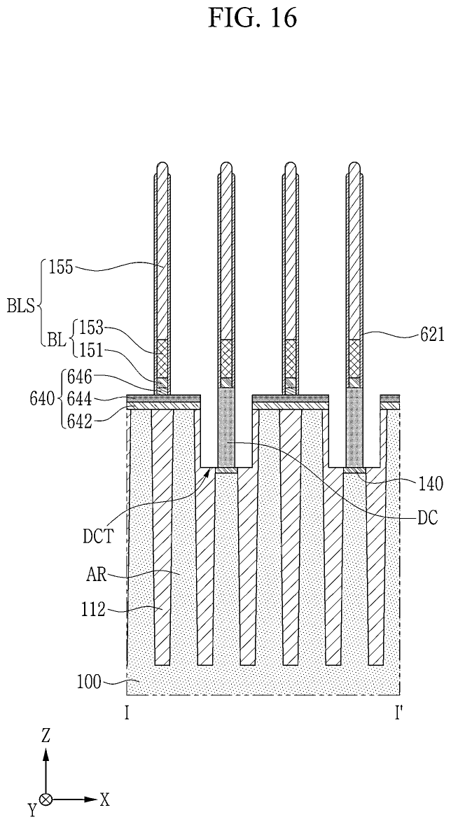

In a process step of forming the direct contact DC, which will be described later with reference to FIG. 15 and FIG. 16, the trench spacer 650 may be a portion of the trench spacer 650 remaining after being etched along with a first material layer 150a among the trench spacers 650 disposed on the inner sidewall of the direct contact trench DCT. A detailed description of this will be described later.

The trench spacer 650 may include a metal, a metal nitride, or any combination thereof. For example, the trench spacer 650 may include a metal such as Ti or Ta and/or a metal nitride such as TiN or TaN.

As another example, the trench spacer 650 may include a metal such as W, Mo, Au, Cu, Al, Ni, or Co. However, the material included in the trench spacer 650 is not limited thereto, and may be variously changed.

The direct contact DC may be disposed within the direct contact trench DCT. The direct contact DC may be substantially disposed at a central portion of the direct contact trench DCT.

A side surface of the direct contact trench DC disposed in the second direction Y in the direct contact trench DCT may directly contact the trench spacer 650. A side surface of the direct contact DC disposed in the first direction X in the direct contact trench DCT may be spaced apart from the trench spacer 650 and the inner surface of the direct contact trench DCT.

The word lines WL may be disposed on both sides (e.g., opposite sides) of the direct contact DC, and the word direct contact DC may overlap the word lines WL in the third direction Z. The lower surface DC_B of the direct contact DC may be disposed at a higher level than the upper surface WL_U of the word line WL.

As described herein, a “level” of an element (e.g., a surface thereof) may be understood to refer to a distance of the element from a reference location (e.g., a lower surface 100b of the substrate 100) in the third direction Z). When one element is described to be at a higher level than another element, the one element may be understood to be located further from the reference location in the positive third direction +Z than the other element.

The trench spacer 650 and the word line capping layer 134 may be disposed between the direct contact DC and the word lines WL. One side surface of the trench spacer 650 may contact the direct contact DC, and the other side surface thereof may contact the word line capping layer 134.

Accordingly, the word line WL and the direct contact DC may be insulated by the trench spacer 650 and the word line capping layer 134.

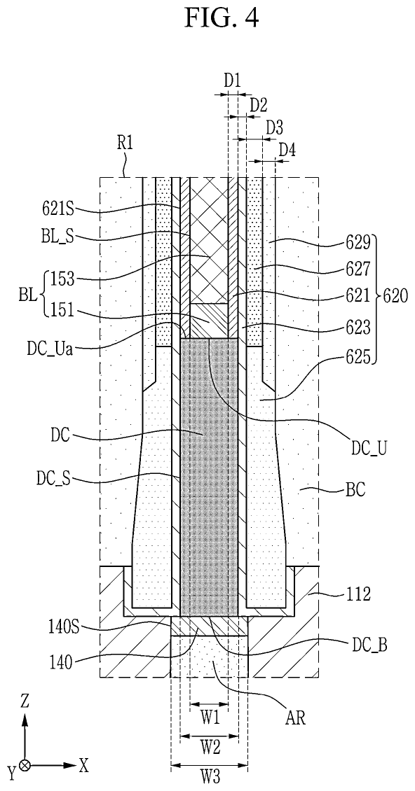

A silicide layer 140 may be disposed between the direct contact DC and the active region AR (e.g., an upper surface of the active region AR as shown in at least FIG. 4). The direct contact DC may be connected by the silicide layer 140 disposed between the active region AR and the direct contact DC. That is, an upper surface of the silicide layer 140 may contact the direct contact DC, and a lower surface of the silicide layer 140 may contact the active region AR.

The silicide layer 140 may include a metal silicide material. For example, the silicide layer 140 may include a metal silicide material such as a titanium silicide, a cobalt silicide, a nickel silicide, and a manganese silicide. However, the material included in the silicide layer 140 is not limited thereto, and may be variously changed.

The direct contact DC may include a metallic material. The metallic material may include a metal, a metal nitride, or any combination thereof. For example, the direct contact DC may include a metal such as Ti or Ta and/or a metal nitride such as TiN or TaN.

As another example, the direct contact DC may include a metal such as W, Mo, Au, Cu, Al, Ni, or Co. However, the material included in the direct contact DC is not limited thereto, and may be variously changed.

As described above, as the silicide layer 140 is disposed between the active region AR and the direct contact DC, which include different materials, the electrical contact between the active region AR and the direct contact DC may be improved.

The bit line BL may be disposed on the substrate 100 and the direct contact DC. That is, some of the bit lines BL may be disposed on the device isolation layer 112, and the remaining bit lines BL may be disposed on the direct contact DC.

In the semiconductor device according to some example embodiments, the bit line BL may include a metallic material different from that of the direct contact DC. The bit line BL may include a plurality of layers that are sequentially stacked, and at least one of the plurality of layers configuring the bit line BL may include a metallic material different from that of the direct contact DC. For example, the bit line BL may include a first conductive layer 151 and a second conductive layer 153, and at least one of the first conductive layer 151 or the second conductive layer 153 may include a metallic material different from the direct contact DC.

Specifically, the first conductive layer 151 and the second conductive layer 153 may include a conductive material. For example, the first conductive layer 151 may include a metal such as Ti or Ta and/or a metal nitride such as TIN or TaN. The second conductive layer 153 may include a metal such as W, Mo, Au, Cu, Al, Ni, or Co. However, the number and material of the conductive layers configuring the bit line BL are not limited thereto, and may be variously changed.

For example, the bit line BL may further include conductive layers other than the first conductive layer 151 and the second conductive layer 153, and the bit line BL may include three conductive layers or four conductive layers. As another example, the first conductive layer 151 may include a metal such as W, Mo, Au, Cu, Al, Ni, and Co, and the second conductive layer 153 may include a metal such as Ti and Ta and/or a metal nitride such as TIN and TaN.

The first conductive layer 151 of the bit line BL disposed on the device isolation layer 112 may be disposed at a level higher than the upper surface of the direct contact DC.

The bit line BL disposed on the direct contact DC may directly contact the direct contact DC. That is, the first conductive layer 151 of the bit line BL may directly contact the upper surface of the direct contact DC.

A bit line capping layer 155 may be disposed on the bit line BL. The bit line BL and the bit line capping layer 155 may form a bit line structure BLS. The bit line capping layer 155 may overlap the bit line BL and the direct contact DC in the third direction Z.

The bit line BL and the direct contact DC may be patterned by using the bit line capping layer 155 as a mask. A planar shape of the bit line BL may be substantially the same as that of the bit line capping layer 155.

The bit line capping layer 155 is shown as being in contact with the second conductive layer 153 of the bit line BL, but is not limited thereto. Another layer may be further disposed between the bit line capping layer 155 and the second conductive layer 153 of the bit line BL.

The bit line capping layer 155 may include a silicon nitride. However, the material of the bit line capping layer 155 is not limited thereto, and may be variously changed.

The bit line spacer structure 620 may be disposed on both sides of the bit line structure BLS. The bit line spacer structure 620 may cover side surfaces of the bit line capping layer 155, the bit line BL, and the direct contact DC.

The bit line spacer structure 620 may substantially extend in the third direction Z along the side surface of the bit line structure BLS. At least a portion of the bit line spacer structure 620 may be disposed within the direct contact trench DCT. In the direct contact trench DCT, the bit line spacer structure 620 may be disposed on both sides of the direct contact DC.

The bit line spacer structure 620 may be formed of a multilayer made of a combination of various types of insulating materials.

The bit line spacer structure 620 may include a first bit line spacer 621, a second bit line spacer 623, a third bit line spacer 625, a fourth bit line spacer 627, and a fifth bit line spacer 629. However, it is not limited thereto, and the number and structure of layers configuring the bit line spacer structure 620 may be variously changed.

In addition, the bit line spacer structure 620 may be formed of a single layer. In some cases, the bit line spacer structure 620 may be formed as an air spacer structure surrounded by spacers and having an air space.

The first bit line spacer 621 may be disposed on the upper surface of the direct contact DC. The first bit line spacer 621 may cover the side surface of the bit line structure BLS. The first bit line spacer 621 may cover the upper surface of the direct contact DC. That is, the first bit line spacer 621 may cover the upper surface of the direct contact DC that does not overlap the bit line structure BLS in the third direction Z among the upper surfaces of the direct contact DC. For example, referring to FIG. 4, the first bit line spacer 621 may cover (e.g., directly contact) the side surface BL_S of the bit line BL and may further cover (e.g., directly contact) at least a portion DC_Ua of the upper surface DC_U of the direct contact DC that does not overlap (e.g., is exposed from) the bit line BL in the third direction Z.

Accordingly, the upper surface of the direct contact DC may directly contact the first conductive layer 151 of the bit line BL and the first bit line spacer 621, and the upper surface of the direct contact DC may be entirely covered by the first conductive layer 151 of the bit line BL and the first bit line spacer 621.

The second bit line spacer 623 may be disposed on the first bit line spacer 621. The second bit line spacer 623 may cover the side surface of the first bit line spacer 621 and the side surface of the direct contact DC. A portion of the second bit line spacer 623 is disposed within the direct contact trench DCT, and may cover the upper surface of the silicide layer 140 and the side surface and bottom surface of the direct contact trench DCT.

The third bit line spacer 625 may be disposed on the second bit line spacer 623. The lower surface and side surface of the third bit line spacer 625 may be surrounded by the second bit line spacer 623. The third bit line spacer 625 may be disposed within the direct contact trench DCT. The third bit line spacer 625 may fill the direct contact trench DCT. The third bit line spacer 625 may be disposed on both sides of the direct contact DC within the direct contact trench DCT.

The fourth bit line spacer 627 may be disposed on the second bit line spacer 623 and the third bit line spacer 625. That is, the fourth bit line spacer 627 may be disposed on the side surface of the second bit line spacer 623 and the upper surface of the third bit line spacer 625.

The fourth bit line spacer 627 may overlap the second bit line spacer 623 in the first direction X, and may overlap the third bit line spacer 625 in the third direction Z. The fourth bit line spacer 627 may substantially extend in the third direction Z along the side surface of the second bit line spacer 623.

The fifth bit line spacer 629 may be disposed on the third bit line spacer 625 and the fourth bit line spacer 627. The fifth bit line spacer 629 may be disposed on the upper surface of the third bit line spacer 625 and the side surface of the fourth bit line spacer 627.

The fifth bit line spacer 629 may overlap the third bit line spacer 625 in the third direction Z, and may overlap the third bit line spacer 625 and the fourth bit line spacer 627 in the first direction X. The fifth bit line spacer 629 may substantially extend in the third direction Z along the side surface of the fourth bit line spacer 627. The fifth bit line spacer 629 may extend parallel to the first bit line spacer 621, the second bit line spacer 623, and the fourth bit line spacer 627. The lower surface and the side surface of the fifth bit line spacer 629 may contact the third bit line spacer 625 and the fourth bit line spacer 627.

The bit line spacer structure 620 may include an insulating material. At least one of the first bit line spacer 621, the second bit line spacer 623, the third bit line spacer 625, the fourth bit line spacer 627, or the fifth bit line spacer 629 may include a different material.

Each of the first bit line spacer 621, the second bit line spacer 623, the third bit line spacer 625, the fourth bit line spacer 627, and the fifth bit line spacer 629 may include at least one of a silicon oxide, a silicon nitride, a silicon oxynitride, or a low-k material with a low dielectric constant, such as SiOCN, SiOC, SiBN, SiBCN, and/or SiBCON.

For example, the first bit line spacer 621 may include a low-k materials with a low dielectric constant, such as SiOCN, SiOC, SiBN, SiBCN, and SiBCON, the second bit line spacer 623, the third bit line spacer 625, and the fifth bit line spacer 629 may include a silicon nitride, and the fourth bit line spacer 627 may include a silicon oxide.

As another example, the first bit line spacer 621 may include a silicon oxide or a silicon nitride, the second bit line spacer 623, the third bit line spacer 625, and the fifth bit line spacer 629 may include a silicon nitride, and the fourth bit line spacer 627 may include a silicon oxide. However, the material included in the bit line spacer structure 620 is not limited thereto, and may be variously changed.

An insulating layer 640 may be disposed under the bit line BL. The insulating layer 640 may be disposed between the bit line (BL) and the device isolation layer 112. The silicide layer 140 and the direct contact DC are disposed between the bit line BL and the active region AR, but the insulating layer 640 may not be disposed therebetween.

The insulating layer 640 may be disposed on the word line structure WLS. The insulating layer 640 may be disposed between the word line structure WLS and the bit line BL. The insulating layer 640 may include a first insulating layer 642, a second insulating layer 644, and a third insulating layer 646 sequentially stacked from below.

At least some of the first insulating layer 642, the second insulating layer 644, and the third insulating layer 646 may have different widths. For example, the widths of the first insulating layer 642 and the second insulating layer 644 may be substantially the same, and the width of the third insulating layer 646 may be smaller than that of the first insulating layer 642 and the second insulating layer 644. The width of the third insulating layer 646 may be greater than that of the bit line BL and the bit line capping layer 155. In addition, the widths of the first insulating layer 642 and the second insulating layer 644 may be greater than the width of the bit line BL and the width of the bit line capping layer 155.

The insulating layer 640 may be covered by the bit line spacer structure 620. For example, an upper surface of the third insulating layer 646 may be covered by the first bit line spacer 621, and a side surface of the third insulating layer 646 may be covered by the second bit line spacer 623. An upper surface of the second insulating layer 644 may be covered by the second bit line spacer 623 and the fifth bit line spacer 629.

The insulating layer 640 may include an insulating material. That is, each of the first insulating layer 642, the second insulating layer 644, and the third insulating layer 646 may include an insulating material. For example, the first insulating layer 642 may include a silicon oxide. The second insulating layer 644 may include a material having an etch selectivity different from that of the first insulating layer 642. For example, the second insulating layer 644 may include a silicon nitride. For example, the third insulating layer 646 may include a silicon oxide or a silicon nitride. However, the configuration, width, and material of the insulating layer 640 are not limited thereto, and may be variously changed.

The semiconductor device according to some example embodiments may include a plurality of buried contacts BC. The buried contact BC may be disposed between the plurality of bit lines BL (e.g., between adjacent bit lines BL in at least the first direction X, for example as shown in FIG. 2).

The plurality of buried contacts BC may be arranged to be spaced apart from each other along the first direction X and the second direction Y. For example, the plurality of buried contacts BC may be arranged to be spaced apart from each other in the second direction Y between two adjacent bit lines BL.

In addition, the plurality of buried contacts BC may be arranged to be spaced apart from each other in the first direction X between two adjacent word lines WL. However, the arrangement form of the plurality of buried contacts BC is not limited thereto, and may be variously changed.

At least a portion of the buried contact BC may overlap the active region AR in the third direction Z, and another portion thereof may overlap the device isolation layer 112 in the third direction Z.

The buried contact BC may be electrically connected to the active region AR. The buried contact BC may directly contact the active region AR. At least some of the lower surface and the side surface of the buried contact BC may be surrounded by the active region AR. However, it is not limited thereto, and another layer may be further disposed between the buried contact BC and the active region AR, and the buried contact BC may be connected to the active region AR through another layer.

The bit line spacer structure 620 may be disposed on both sides of the buried contact BC. That is, the bit line spacer structure 620 may be disposed between the buried contact BC and the bit line BL.

For example, one side surface of the buried contact BC may contact the active region AR, the insulating layer 640, and the fifth bit line spacer 629, and the other side surface of the buried contact BC may contact the third bit line spacer 625 and the fifth bit line spacer 629. The lower surface of the buried contact BC may contact the device isolation layer 112 and the first bit line spacer 621. However, the disposition relationship between the buried contact BC and the bit line spacer structure 620 is not limited thereto, and may be variously changed.

The upper surface of the buried contact BC may be disposed at a higher level than the upper surface of the bit line BL, and the lower surface of the buried contact BC may be disposed at a level between the upper surface and the lower surface of the direct contact DC. However, the disposition relationship between the buried contact BC and the bit line BL and between the buried contact BC and the direct contact DC is not limited thereto, and may be variously changed.

The buried contact BC may include a conductive material. For example, the buried contact BC may include polysilicon doped with impurities, but is not limited thereto.

The semiconductor device according to some example embodiments may include a plurality of landing pads LP.

The landing pad LP may be disposed on the buried contact BC.

The plurality of landing pads LP may be arranged to be spaced apart from each other along the first direction X and the second direction Y. The plurality of landing pads LP may be arranged in a line along the first direction X. The plurality of landing pads LP may be arranged in a zigzag form along the second direction Y. For example, they may be alternately arranged on the left and right sides of the bit line BL. However, the disposition form of the plurality of landing pads LP is not limited thereto, and may be variously changed.

The landing pad LP may cover the upper surface of the buried contact BC, and may overlap the buried contact BC in the third direction Z. At least a portion of the landing pad LP may overlap the bit line spacer structure 620 in the third direction Z, and may overlap the bit line BL in the third direction Z.

The upper surface of the landing pad LP may be disposed at a higher level than the upper surface of the bit line capping layer 155. The bit line spacer structure 620 may be disposed on both sides of the landing pad LP. The bit line spacer structure 620 may be disposed between the landing pad LP and the bit line capping layer 155.

The landing pad LP may be electrically connected to the buried contact BC. The landing pad LP may directly contact the buried contact BC. The landing pad LP may be electrically connected to the active region AR through the buried contact BC.

The landing pad LP may include a metal silicide layer 171, a conductive barrier layer 173, and a conductive layer 175.

The metal silicide layer 171 may be disposed on the buried contact BC, the conductive barrier layer 173 may be disposed on the metal silicide layer 171, and the conductive layer 175 may be disposed on the conductive barrier layer 173.

The metal silicide layer 171 may directly contact the buried contact BC. The metal silicide layer 171 may entirely cover the upper surface of the buried contact BC. The upper surface of the buried contact BC may be formed to have a concave shape toward the buried contact BC, and the metal silicide layer 171 may have a concave shape along the upper surface of the buried contact BC.

The bit line spacer structure 620 may be disposed on both sides of the metal silicide layer 171. For example, the metal silicide layer 171 may contact the fifth bit line spacer 629.

The metal silicide layer 171 may include a metal silicide material such as a cobalt silicide, a nickel silicide, a manganese silicide, or the like. However, the shape and material of the metal silicide layer 171 are not limited thereto, and may be variously changed. In addition, in some example embodiments, the metal silicide layer 171 may be omitted.

The conductive barrier layer 173 may be disposed between the metal silicide layer 171 and the conductive layer 175. The lower surface of the conductive barrier layer 173 may contact the metal silicide layer 171. The bit line spacer structure 620 may be disposed on both side surfaces of the conductive barrier layer 173. For example, the conductive barrier layer 173 may cover upper surfaces of the first bit line spacer 621, the second bit line spacer 623, the fourth bit line spacer 627, and the fifth bit line spacer 629.

The conductive barrier layer 173 may include Ti, TiN, or any combination thereof. However, the shape and material of the conductive barrier layer 173 are not limited thereto, and may be variously changed.

The lower surface of the conductive layer 175 may contact the conductive barrier layer 173. At least some of the lower surface and the side surface of the conductive layer 175 may be surrounded by the conductive barrier layer 173. The conductive barrier layer 173 may be disposed between the conductive layer 175 and the metal silicide layer 171. The conductive barrier layer 173 may be disposed between the conductive layer 175 and the bit line spacer structure 620.

The conductive layer 175 may include metal, a metal nitride, polysilicon doped with impurities, or any combination thereof. For example, the conductive layer 175 may include W. However, the shape and material of the conductive layer 175 are not limited thereto, and may be variously changed.

An insulating pattern 660 may be disposed between a plurality of landing pads LP. The insulating pattern 660 may fill a space between the plurality of landing pads LP. Accordingly, the plurality of landing pads LP may be separated from each other by the insulating pattern 660.

The landing pad LP may include a silicon nitride, a silicon oxynitride, a silicon oxide, or any combination thereof. The landing pad LP may be formed of a single layer or a multilayer.

For example, the landing pad LP may include a first landing pad layer and a second landing pad layer that are stacked. The first landing pad layer may include a silicon oxide or a low-k material having a low dielectric constant such as SiOCH or SiOC, and the second landing pad layer may include a silicon nitride or a silicon oxynitride. However, the shape and material of the landing pad LP are not limited thereto, and may be variously changed.

Although not illustrated, a capacitor structure may be disposed on the landing pad LP. The capacitor structure may include a first capacitor electrode, a second capacitor electrode, and a dielectric layer disposed between the first capacitor electrode and the second capacitor electrode.

The first capacitor electrode may contact the landing pad LP, and may be electrically connected to the landing pad LP. The capacitor structure may be electrically connected to the active region AR through the landing pad LP and the buried contact BC.

The first capacitor electrode may be disposed on each landing pad LP, and a plurality of first capacitor electrodes may be disposed to be separated from each other. The second capacitor electrodes of a plurality of capacitor structures may be applied with the same voltage, and may be integrally formed. Dielectric layers of the plurality of capacitor structures may be integrally formed.

Hereinafter, in a semiconductor device according to some example embodiments with reference to FIG. 4 to FIG. 7, an arrangement relationship of the direct contact DC and components disposed around the direct contact DC, a relationship between a width of the direct contact DC and a width of the bit line BL, and a relationship between widths of the spacers configuring the bit line spacer structure 620 will be described.

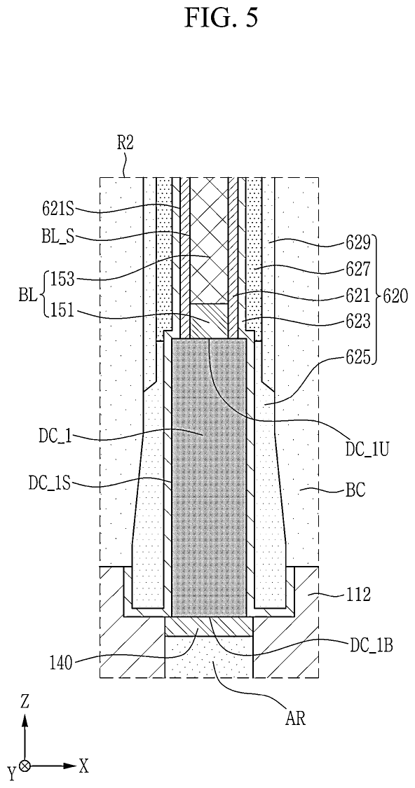

FIG. 4 illustrates a partially enlarged view of region R1 of FIG. 2 according to some example embodiments. FIGS. 5, 6, and 7 illustrate partial enlarged views of cross-sections of a semiconductor device according to some example embodiments.

Specifically, FIG. 5 to FIG. 7 respectively illustrate a region R2, a region R3, and a region R4 corresponding to the region R1 of FIG. 2 according to some example embodiments.

Referring to FIG. 4, as described above, the direct contact DC and the bit line BL may be sequentially disposed on the silicide layer 140. That is, the direct contact DC may be disposed on the silicide layer 140, and the bit line BL (e.g., a lower surface thereof) may be disposed on (e.g., directly or indirectly on) the direct contact DC (e.g., an upper surface DC_U thereof).

Accordingly, a lower surface DC_B of the direct contact DC may directly contact the silicide layer 140, and an upper surface DC_U of the direct contact DC may directly contact the first conductive layer 151 of the bit line BL. However, it is not limited thereto, and in some example embodiments, other layers may be further disposed between the direct contact DC and the silicide layer 140 and between the direct contact DC and the bit line BL.

In some example embodiments, the bit line BL may have a first width W1, the direct contact DC may have a second width W2, and the silicide layer 140 may have a third width W3. Here, the widths may mean widths along the first direction X. As shown, the width of the direct contact DC (e.g., second width W2 in the first direction X) may be different from (e.g., greater than) the width of the bit line BL (e.g., first width W1 in the first direction X).

The first conductive layer 151 and the second conductive layer 153 of the bit line BL may extend in the third direction Z, and may have a constant width along the first direction X. That is, the first conductive layer 151 and the second conductive layer 153 may have the first width W1 according to the first direction X. However, it is not limited thereto, and in some example embodiments, the first conductive layer 151 and the second conductive layer 153 of the bit line BL may have different widths along the first direction X.

The direct contact DC may extend in the third direction Z, and may have a constant width along the first direction X. The widths of the upper surface DC_U and the lower surface DC_B of the direct contact DC may be substantially the same. That is, the upper surface DC_U and the lower surface DC_B of the direct contact DC may have the second width W2 in the first direction X.

In some example embodiments, the first width W1 and the second width W2 may be different. For example, the second width W2 may be greater than the first width W1. That is, the width of the direct contact DC along the first direction X may be greater than the width of the bit line BL along the first direction X.

Accordingly, at least a portion of the upper surface of the direct contact DC may be not covered by the bit line BL. As described above, the upper surface of the portion of the direct contact DC not covered by the bit line BL may be covered by the first bit line spacer 621. The first bit line spacer 621 may directly contact both a side surface BL_S of the bit line BL and an upper surface DC_U of the direct contact DC.

Accordingly, the width of the direct contact DC may be the same or substantially the same as a sum of the width of the bit line BL and the width of the first bit line spacer 621. That is, the width of the first bit line spacer 621 may be the same or substantially the same as (e.g., equal to or substantially equal to) a difference between the width of the direct contact DC and the width of the bit line BL. Here, a width of each constituent element may mean a width along the first direction X.

In some example embodiments, the second width W2 (e.g., a width of the direct contact DC in the first direction X) and the third width W3 (e.g., a width of the silicide layer 140 in the first direction X) may be different. For example, the third width W3 may be greater than the second width W2. That is, the width of the direct contact DC along the first direction X may be smaller than the width of the silicide layer 140 along the first direction X.

The relationship between the first width W1, the second width W2, and the third width W3 has been described above, but it is not limited thereto, and may be variously changed.

As such, since the silicide layer 140, the direct contact DC, and the bit line BL have different widths, their side surfaces may be aligned at different boundaries.

Specifically, a side surface DC_S of the direct contact DC may be disposed on an upper surface of the silicide layer 140. That is, a side surface 140S of the silicide layer 140 may protrude more toward the first direction X than the side surface DC_S of the direct contact DC. In other words, the side surface DC_S of the direct contact DC may be disposed between both side surfaces 140S of the silicide layer 140.

The side surface BL_S of the bit line BL may be disposed on the upper surface DC_U of the direct contact DC. That is, the side surface DC_S of the direct contact DC may protrude more toward the first direction X than the side surface BL_S of the bit line BL. For example, a side surface DC_S of the direct contact DC may protrude outwards (e.g., in the first direction X) from the side surface BL_S of the bit line BL. In other words, the side surface BL_S of the bit line BL may be disposed between both side surfaces DC_S of the direct contact DC.

In addition, the side surface 140S of the silicide layer 140 may be disposed to protrude more toward the first direction X than the side surface BL_S of the bit line BL. In other words, the side surface BL_S of the bit line BL may be disposed between both side surfaces 140S of the silicide layer 140.

In addition, a side surface 621S of the first bit line spacer 621 disposed on the side surface of the bit line BL may be aligned at substantially the same boundary as the side surface DC_S of the direct contact DC. That is, the side surface 621S of the first bit line spacer 621 covering the upper surface of the direct contact DC together with the bit line BL may be aligned at substantially the same boundary as the side surface DC_S of the direct contact DC in the third direction Z. For example, the side surface 621S of the first bit line spacer 621 may, at an interface between the first bit line spacer 621 and the direct contact DC, be coplanar or substantially coplanar with the side surface DC_S of the direct contact DC. In other words, the side surface 621S of the first bit line spacer 621 and the side surface DC_S of the direct contact DC may continuously extend along the third direction Z.

The first bit line spacer 621, the second bit line spacer 623, the fourth bit line spacer 627, and the fifth bit line spacer 629 may have a first thickness D1, a second thickness D2, a third thickness D3, and a fourth thickness D4, respectively. Here, each of the first thickness D1, the second thickness D2, the third thickness D3, and the fourth thickness D4 may mean a thickness along the first direction X. In some example embodiments, the first bit line spacer 621 may have a thickness, for example thickness D1, (e.g., in the first direction X) of about 0.5 nm to about 1 nm.

At least one of the first thickness D1, the second thickness D2, the third thickness D3, or the fourth thickness D4 may be different. For example, the first thickness D1 may be thicker than the second thickness D2 and thinner than the third thickness D3 and the fourth thickness D4. The second thickness D2 may be thinner than the first thickness D1, the third thickness D3, and the fourth thickness D4. The third thickness D3 may be thicker than the first thickness D1, the second thickness D2, and the fourth thickness D4. The fourth thickness D4 may be thicker than the first thickness D1 and the second thickness D2 and thinner than the third thickness D3. That is, the second thickness D2 of the bit line spacer structure 620 may be the thinnest, and the third thickness D3 thereof may be the thickest. However, the relationship between the first thickness D1 of the first bit line spacer 621 included in the bit line spacer structure 620, the second thickness D2 of the second bit line spacer 623, the third thickness D3 of the fourth bit line spacer 627, and the fourth thickness D4 of the fifth bit line spacer 629 is not limited thereto, and may be variously changed.

According to some example embodiments, including the example embodiments of FIG. 5, unlike some example embodiments, including the example embodiments shown in FIG. 4, a side surface DC_1_S of a direct contact DC_1 and the side surface 621S of the first bit line spacer 621 may be aligned at different boundaries. Accordingly, the shape of the bit line spacer structure 620 disposed between the direct contact DC_1 and the buried contact BC may be changed.

Specifically, a side surface DC_1S of the direct contact DC_1 may protrude further in the first direction X than the side surface 621S of the first bit line spacer 621. For example, the side surface DC_1S of the direct contact DC_1 may protrude outward (e.g., in the first direction X) from the side surface 621S of the first bit line spacer 621. Accordingly, the side surface DC_1S of the direct contact DC_1 may be aligned at a different boundary from the side surface 621S of the first bit line spacer 621. That is, the side surface 621S of the first bit line spacer 621 may be disposed between both side surfaces DC_1S of the direct contact DC_1 on the upper surface of the direct contact DC_1. As shown, the width of the lower surface DC_1B of the direct contact DC (e.g., in the first direction X) may be greater than a width of the bit line BL (e.g., in the first direction X).

The first bit line spacer 621 and the second bit line spacer 623 may be disposed on an upper surface DC_1U of the direct contact DC_1. That is, unlike some example embodiments shown in FIG. 4 in which only the first bit line spacer 621 is disposed on the upper surface DC of the direct contact DC, in some example embodiments, the first bit line spacer 621 and the second bit line spacer 623 may be disposed on the upper surface DC_1U of the direct contact DC_1. In other words, the upper surface DC_1U of the direct contact DC_1 may be covered by the bit line BL, the first bit line spacer 621, and the second bit line spacer 623.

As the side surface DC_1S of the direct contact DC_1 protrudes further in the first direction X than the side surface 621S of the first bit line spacer 621, the second bit line spacer 623 may be conformally disposed on the upper surface DC_1U and the side surface DC_1S of the direct contact DC_1.

In addition, as the side surface DC_1S of the direct contact DC_1 protrudes further in the first direction X than the side surface 621S of the first bit line spacer 621, the arrangement shape of the third bit line spacer 625 disposed on the second bit line spacer 623 may be different from the arrangement shape of the third bit line spacer 625 according to some example embodiments shown in FIG. 4.

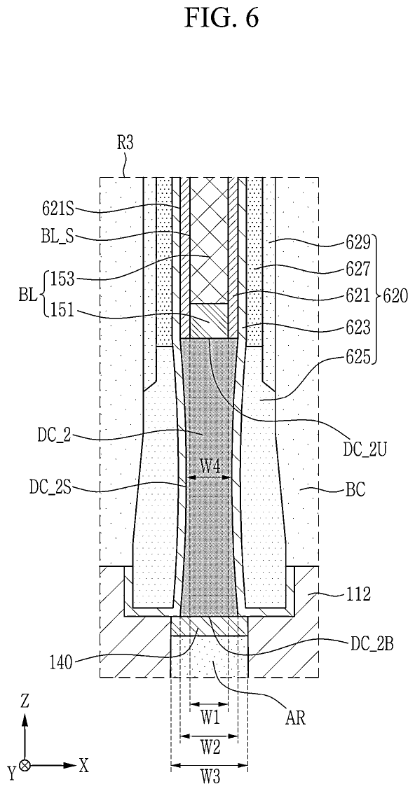

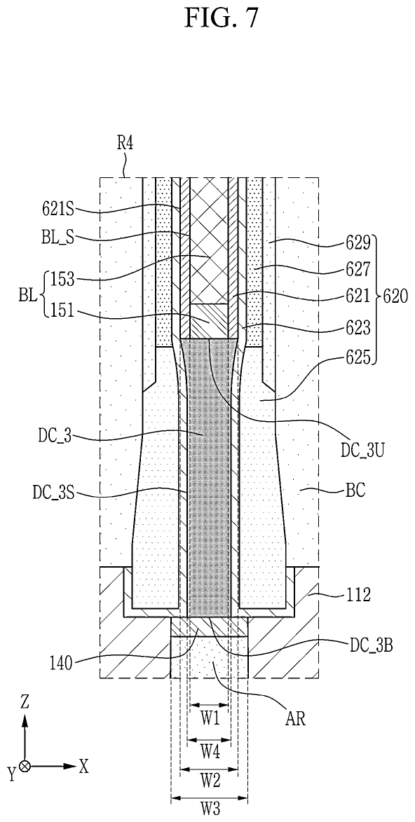

Cross-sectional shapes of direct contacts DC_2 and DC_3 according to embodiments shown in FIG. 6 and FIG. 7 may be different from the cross-sectional shape of the direct contact DC according to some example embodiments shown in FIG. 4. Accordingly, the shape of the bit line spacer structure 620 disposed between the direct contacts DC_2 and DC_3 and the buried contact BC may be changed.

According to some example embodiments shown in FIG. 6, a width of the direct contact DC_2 along the first direction X may decrease from an upper surface DC_2U and a lower surface DC_2B of the direct contact DC_2 toward a central portion of the direct contact DC_2. That is, the width along the first direction X may decrease from the upper surface DC_2U to the central portion of the direct contact DC_2, and the width along the first direction X may increase from the central of the direct contact DC_2 to the lower surface DC_2B of the direct contact DC_2.

In addition, a side surface DC_2S of the direct contact DC_2 according to some example embodiments may include a curved line. That is, both side surfaces DC_2S of the direct contact DC_2 may have a concave shape toward a central axis of the direct contact DC_2. However, the shape of the side surface DC_2S of the direct contact DC_2 is not limited thereto, and may be variously changed. For example, the side surface DC_2S of the direct contact DC_2 may include a straight shape other than a curved line.

Accordingly, the side surface of the second bit line spacer 623 disposed along the profile of the side surface DC_2S of the direct contact DC_2 between the direct contact DC_2 and the buried contact BC may include a curved line. In addition, the side surface of the third bit line spacer 625 disposed on the second bit line spacer 623 between the direct contact DC_2 and the buried contact BC may also include a curved line.

The bit line BL may have a first width W1 along the first direction X, the upper surface DC_2U and the lower surface DC_2B of the direct contact DC_2 may have a second width W2 along the first direction X, the silicide layer 140 may have a third width W3 in the first direction X, and the central portion of the direct contact DC_2 may have a fourth width W4 in the first direction X.

In some example embodiments, at least one of the first width W1, the second width W2, the third width W3, or the fourth width W4 may be different. For example, the second width W2 may be greater than the first width W1, and the third width W3 may be greater than the second width W2. In addition, the fourth width W4 may be greater than the first width W1 and smaller than the second width W2 and the third width W3. However, it is not limited thereto, and the relationship between the first width W1, the second width W2, the third width W3, and the fourth width W4 may be variously changed.

According to some example embodiments, including the example embodiments shown in FIG. 7, a side surface DC_3S of the direct contact DC_3 may include both a curved line and a straight line, unlike the side surface DC_2S of the direct contact DC_2 shown in FIG. 6. That is, a portion of the side surface DC_3S of the direct contact DC_3 disposed on the direct contact DC_3 and connected to the upper surface DC_3U of the direct contact DC_3 includes a curved line, and the remaining side surface DC_3S of the direct contact DC_3 may include a straight line.

The width of the direct contact DC_3 along the first direction X may decrease from the upper surface DC3_U to the lower surface DC_3B of the direct contact DC_3 and then may be maintained constant. That is, the width along the first direction X of the direct contact DC_3 portion including the curved line among the side surfaces DC_3S of the direct contact DC_3 may decrease from the upper surface DC_3U to the lower surface DC_3B of the direct contact DC_3, and the width along the first direction X of the direct contact DC_3 portion including the straight line among the side surfaces DC_3S of the direct contact DC_3 may be maintained constant.

Accordingly, the upper surface DC_3U and the lower surface DC_3B of the direct contact DC_3 may have different widths in the first direction X. As shown, the width of the upper surface DC_3U of the direct contact DC (e.g., second width W2 in the first direction X) may be greater than a width of the lower surface DC_3B of the direct contact DC (e.g., fourth width W4 in the first direction X). In addition, the side surface of the second bit line spacer 623 disposed along the profile of the side surface DC_3S of the direct contact DC_3 between the direct contact DC_3 and the buried contact BC, and the side surface of the third bit line spacer 625 may have substantially the same shape as the side surface DC_3S of the direct contact DC_3.

The bit line BL may have the first width W1 along the first direction X, the upper surface DC_3U of the direct contact DC_3 may have the second width W2 along the first direction X, the silicide layer 140 may have the third width W3 in the first direction X, and the lower surface DC_3B of the direct contact DC_3 may have the fourth width W4 along the first direction X.

In some example embodiments, at least one of the first width W1, the second width W2, the third width W3, or the fourth width W4 may be different. For example, the first width W1 may be smaller than the second width W2, the third width W3, and the fourth width W4. The second width W2 may be greater than the first width W1 and the fourth width W4 and smaller than the third width W3. The third width W3 may be greater than the first width W1, the second width W2, and the fourth width W4. The fourth width W4 may be greater than the first width W1 and smaller than the second width W2 and the third width W3.

That is, the width of the upper surface DC_3U of the direct contact DC_3 along the first direction X may be greater than the width of the lower surface DC_3B of the direct contact DC_3 along the first direction X, and the width of the lower surface DC_3B of the direct contact DC_3 along the first direction X may be greater than that of the bit line BL along the first direction X. However, it is not limited thereto, and the relationship between the first width W1, the second width W2, the third width W3, and the fourth width W4 may be variously changed. For example, the fourth width W4 may be greater than the second width W2.

According to the semiconductor device according to some example embodiments, as the first bit line spacer 621 is disposed on the side surface of the bit line BL disposed on the direct contacts DC, DC_1, DC_2, and DC_3, it is possible to prevent the side surface of the bit line BL from being exposed during a fabricating process of the semiconductor device.

Accordingly, it is possible to prevent the bit line BL from being damaged due to galvanic corrosion between the bit line BL including the conductive material and the direct contacts DC, DC_1, DC_2, and DC_3 including the conductive material by a cleaning material during the fabricating process of the semiconductor device. A detailed description of this will be described later.

In addition, when the first bit line spacer 621 disposed on the side surface of the bit line BL includes a low-k material, it is possible to prevent the bit line BL from being damaged and to reduce parasitic capacitance that may occur between the bit line BL and the buried contact BC.

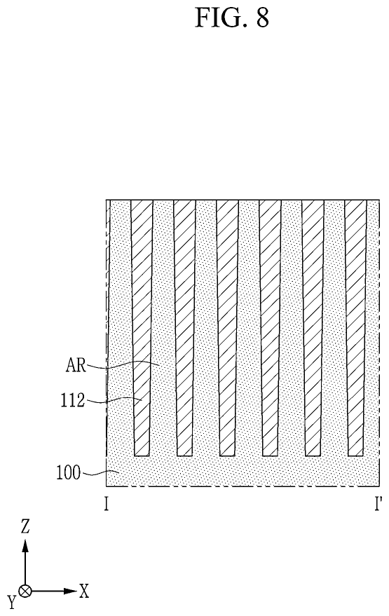

Hereinafter, a semiconductor device according to some example embodiments will be described with reference to FIG. 8 to FIG. 20. In some example embodiments, including the example embodiments shown in FIGS. 8 to 20, the same components as those in the previously described example embodiments are denoted by the same reference numerals, and redundant descriptions thereof will be omitted or simplified, and differences will be mainly described.

FIGS. 8, 9, 10, 11, 12, 13, 14, 15, 16, 17, 18, 19, and 20 illustrate cross-sectional views for explaining a method for fabricating a semiconductor device according to some example embodiments.

Specifically, FIG. 8 to FIG. 20 illustrate cross-sectional views taken along line I-I′ in FIG. 1 in respective fabricating process steps to explain a method for fabricating a semiconductor device according to some example embodiments.

First, referring to FIG. 8, a trench for isolating a plurality of devices may be formed in the substrate 100, and the device isolation layer 112 may be formed to fill the trench. A plurality of active regions AR may be defined by the device isolation layer 112.

The plurality of active regions AR may be disposed within the substrate 100, and the plurality of active regions AR may be isolated from each other by the device isolation layer 112. The device isolation layers 112 may be disposed on both sides (e.g., opposite sides) of each active region AR.

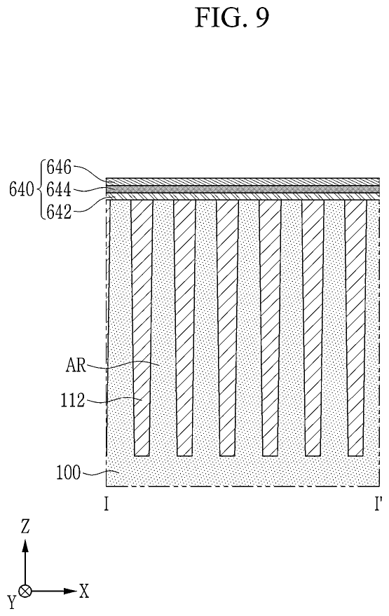

Subsequently, referring to FIG. 9, the first insulating layer 642, the second insulating layer 644, and the third insulating layer 646 of the insulating layer 640 may be sequentially stacked on the substrate 100 to cover the active region AR and the device isolation layer 112.

Accordingly, the first insulating layer 642, the second insulating layer 644, and the third insulating layer 646 may configure the insulating layer 640. However, the structure of the insulating layer 640 is not limited thereto, and the insulating layer 640 may be formed as a single layer, a double layer, or four or more insulating layers.

The first insulating layer 642, the second insulating layer 644, and the third insulating layer 646 may each be made of an insulating material. For example, the first insulating layer 642 may include a silicon oxide. The second insulating layer 644 may include a material having an etch selectivity different from that of the first insulating layer 642. For example, the second insulating layer 644 may include a silicon nitride. For example, the third insulating layer 646 may include a silicon oxide or a silicon nitride. However, the material of the insulating layer 640 is not limited thereto, and may be variously changed.

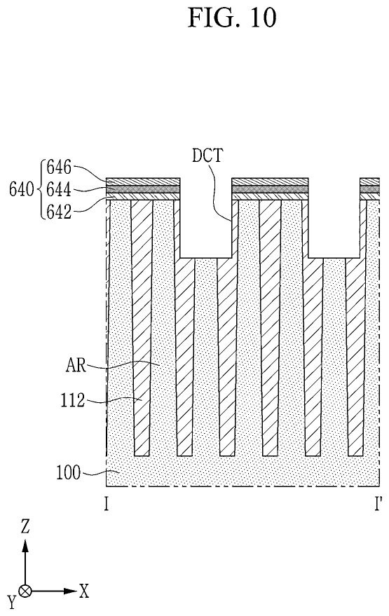

Next, referring to FIG. 10, the direct contact trench DCT exposing at least a portion of the active region AR may be formed by patterning the insulating layer 640, the device isolation layer 112, and a portion of the active region AR.

The direct contact trench (DCT) may be formed by forming a hard mask layer on the insulating layer 640, patterning the hard mask layer using a photo and etching process, and then using the hard mask pattern.

That is, the third insulating layer 646, the second insulating layer 644, and the first insulating layer 642 may be sequentially etched using the hard mask pattern. When the first insulating layer 642 is etched, the active region AR of the substrate 100 and the upper surface of the device isolation layer 112 may be exposed. Subsequently, the direct contact trench DCT may be formed by etching the active region AR and the device isolation layer 112.

The active region AR may be disposed approximately at the central portion of the direct contact trench DCT. The active region AR and the device isolation layer 112 may configure a bottom surface of the direct contact trench DCT. The device isolation layer 112 and the insulating layer 640 may configure a sidewall of the direct contact trench DCT.

The direct contact trench DCT may have a substantial quadrangular shape in a cross-sectional view. However, the shape of the direct contact trench DCT is not limited thereto, and may be variously changed. For example, the direct contact trench DCT may have a shape of which the width becomes narrower toward the bottom surface. However, the formation method and shape of the direct contact trench DCT are not limited thereto, and may be variously changed.

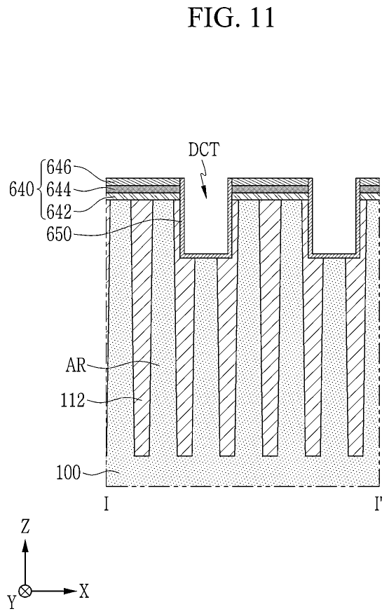

Subsequently, referring to FIG. 11, the trench spacer 650 may be formed in the direct contact trench DCT. That is, the trench spacer 650 may be conformally formed along the profile of the sidewall and bottom surface of the direct contact trench DCT. Accordingly, the trench spacer 650 may be disposed on the active region AR (e.g., an exposed upper surface of the active region AR, the device isolation layer 112, and the insulating layer 640.

The trench spacer 650 may include a metal, a metal nitride, or any combination thereof. For example, the trench spacer 650 may include a metal such as Ti or Ta and/or a metal nitride such as TiN or TaN. As another example, the trench spacer 650 may include a metal such as W, Mo, Au, Cu, Al, Ni, or Co. However, the material included in the trench spacer 650 is not limited thereto, and may be variously changed according to a first material layer (referred to as ‘150a’ in FIG. 15) to be described later, and in some example embodiments, the trench spacer 650 may be omitted.

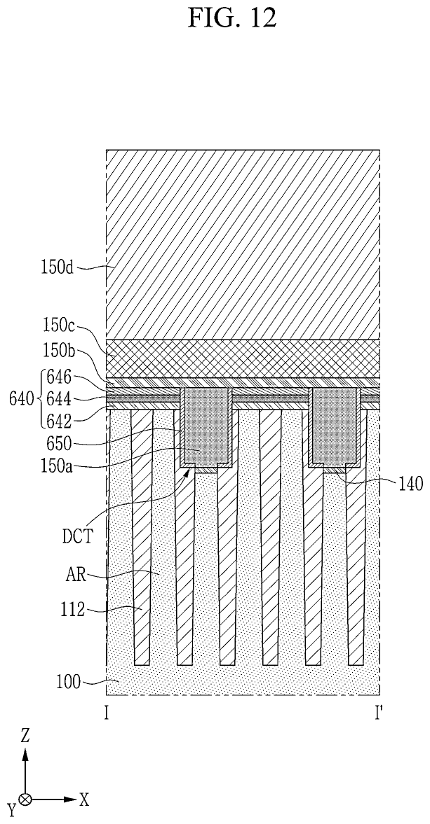

Subsequently, referring to FIG. 12, the upper surface of the active region AR may be exposed by etching a portion of the trench spacer 650. That is, the upper surface of the active region AR may be exposed by etching a portion of the trench spacer 650 disposed on the bottom surface of the direct contact trench DCT.

In some example embodiments, a process step of etching a portion of the trench spacer 650 may be performed simultaneously in a patterning step after forming the trench spacer 650.

Subsequently, the first material layer 150a may be formed in the direct contact trench DCT. That is, the first material layer 150a may be formed on the trench spacer 650 and the active region AR.

First, the trench spacer 650 is formed in the direct contact trench DCT of the substrate 100, and then in a state in which the trench spacer 650 is etched so that the upper surface of the active region AR is exposed, the first material layer 150a may be formed to fill the inside of the direct contact trench DCT.

Subsequently, when a planarization process is performed until the upper surface of the insulating layer 640 is exposed, the upper surfaces of the first material layer 150a and the insulating layer 640 may be planarized. That is, the upper surface of the first material layer 150a and the upper surface of the third insulating layer 646 may be disposed at substantially the same level.

The lower surface of the first material layer 150a may contact the active region AR and the trench spacer 650. The side surface of the first material layer 150a may contact the trench spacer 650. The upper surface of the first material layer 150a and the upper surface of the insulating layer 640 may be flat.

The first material layer 150a may include a metallic material. For example the first material layer 150a may include a metal, a metal nitride, or any combination thereof. For example, the first material layer 150a may include a metal such as Ti or Ta and/or a metal nitride such as TiN or TaN.

As another example, the first material layer 150a may include a metal such as W, Mo, Au, Cu, Al, Ni, or Co. However, the material included in the direct contact DC is not limited thereto, and may be variously changed.

The silicide layer 140 may be formed between the upper surface of the active region AR exposed by the trench spacer 650 and the first material layer 150a. That is, it may be formed by reacting the metal included in the first material layer 150a with the silicon included in the active region AR. In other words, after forming the first material layer 150a on the active region AR exposed by the trench spacer 650 so that the active region AR and the first material layer 150a come into contact with each other, when an annealing process is performed, a material included in the first material layer 150a and a material included in the active region AR may react to form a silicide layer 140 at an interface between the first material layer 150a and the active region AR.

The silicide layer 140 may include a metal silicide material. For example, the silicide layer 140 may include a metal silicide material such as a titanium silicide, a cobalt silicide, a nickel silicide, and a manganese silicide. However, the material included in the silicide layer 140 and the method for forming the silicide layer 140 are not limited thereto, and may be variously changed.

Subsequently, the second material layer 150b, the third material layer 150c, and the fourth material layer 150d may be sequentially stacked on the first material layer.

The lower surface of the second material layer 150b may contact the insulating layer 640, the first material layer 150a, and the trench spacer 650. The second material layer 150b may be disposed between the first material layer 150a and the third material layer 150c, and may be disposed between the insulating layer 640 and the third material layer 150c. The upper surface of the second material layer 150b may contact the third material layer 150c, and the upper surface of the third material layer 150c may contact the fourth material layer 150d.

The second material layer 150b and the third material layer 150c may include a conductive material. For example, the second material layer 150b may include a metal such as Ti or Ta and/or a metal nitride such as TiN or TaN. The third material layer 150c may include a metal such as W, Mo, Au, Cu, Al, Ni, or Co. The fourth material layer 150d may include an insulating material. For example, it may include a silicon nitride. However, the materials included in the second material layer 150b, the third material layer 150c, and the fourth material layer 150d are not limited thereto, and may be variously changed.

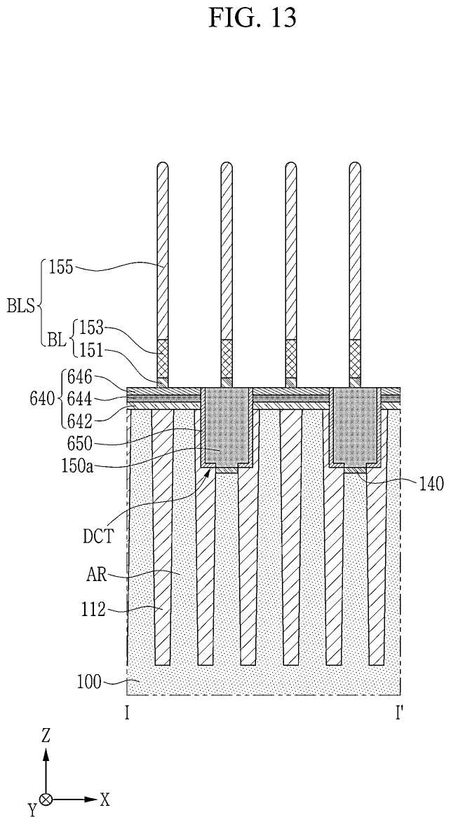

Subsequently, referring to FIG. 13, the fourth material layer 150d, the third material layer 150c, and the second material layer 150b may be patterned. That is, at least some of the fourth material layer 150d, the third material layer 150c, and the second material layer 150b may be removed by performing a photo and etching process. The bit line structure BLS may be formed through the patterning process. In addition, in the step of patterning the fourth material layer 150d, the third material layer 150c, and the second material layer 150b, the upper surface of the bit line structure BLS may be patterned to have a curved shape.

Specifically, the bit line structure BLS may be formed by patterning the second material layer 150b, the third material layer 150c, and the fourth material layer 150d. The bit line structure BLS may include the bit line BL and the bit line capping layer 155.

The first conductive layer 151 of the bit line BL may be formed by patterning the second material layer 150b, and the second conductive layer 153 of the bit line BL may be formed by patterning the third material layer 150c. In addition, the bit line capping layer 155 may be formed by patterning the fourth material layer 150d.

The second conductive layer 153 may be disposed on the first conductive layer 151 of the bit line BL, and the bit line capping layer 155 may be disposed on the second conductive layer 153. In addition, the first conductive layer 151, the second conductive layer 153, and the bit line capping layer 155 of the bit line BL may be sequentially disposed on the upper surface of the first material layer 150a.

As the second material layer 150b is removed, the third insulating layer 646 disposed under the second material layer 150b may be exposed to the outside. As the third insulating layer 646 includes a material having an etch selectivity different from that of the second material layer 150b, the third insulating layer 646 may serve as an etch stop film in the step of patterning the fourth material layer 150d, the third material layer 150c, and the second material layer 150b.

In some example embodiments, when patterning the fourth material layer 150d, the third material layer 150c, and the second material layer 150b, the third insulating layer 646 may be etched together and disposed below the third insulating layer 646, and the second insulating layer 644 having an etch selectivity different from that of the third insulating layer 646 may be exposed.

In some example embodiments, when patterning the fourth material layer 150d, the third material layer 150c, and the second material layer 150b, the second insulating layer 644 and the third insulating layer 646 may be etched together and disposed below the second insulating layer 644, and the first insulating layer 642 having an etch selectivity different from that of the second insulating layer 644 may be exposed.

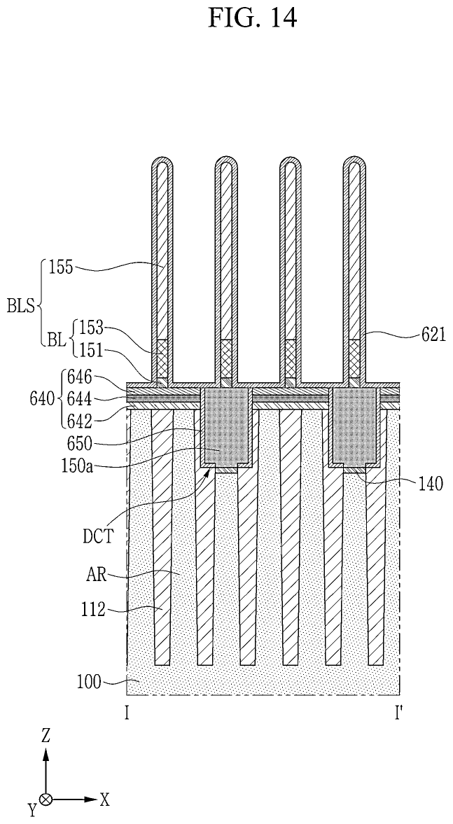

Subsequently, referring to FIG. 14, the first bit line spacer 621 may be formed using an insulating material on the bit line structure BLS. The first bit line spacer 621 may be conformally formed to cover the upper and side surfaces of the bit line structure BLS.

In addition, the first bit line spacer 621 may conformally cover the upper surface of the insulating layer 640, the upper surface of the trench spacer 650, and the upper surface of the first material layer 150a.

The first bit line spacer 621 may include an insulating material. For example, the first bit line spacer 621 may include at least one of a silicon oxide, a silicon nitride, or a low-k material having a low dielectric constant such as SiOCN, SiOC, SiBN, SiBCN, or SiBCON. However, the material included in the first bit line spacer 621 is not limited thereto, and may be variously changed.

Subsequently, referring to FIG. 15, the first bit line spacer 621 may be patterned. That is, by patterning the first bit line spacer 621, at least a portion of the first bit line spacer 621 may be removed.

Specifically, the first bit line spacer 621 disposed between the bit line structures BLS and on the upper surface of the bit line structures BLS may be removed. That is, the first bit line spacer 621 disposed on the upper surface of the bit line structure BLS, the upper surface of the insulating layer 640, the upper surface of the trench spacer 650, and the upper surface of the first material layer 150a may be removed.

Accordingly, the first bit line spacer 621 may be disposed on the side surface of the bit line structure BLS. As a portion of the first bit line spacer 621 is removed, the upper surface of the bit line structure BLS disposed under the first bit line spacer 621, the upper surface of the insulating layer 640, the upper surface of the trench spacer 650, and the upper surface of the first material layer 150a may be exposed.

In addition, in the step of patterning the first bit line spacer 621, a thickness of the first bit line spacer 621 may be reduced. Here, the thickness may mean a thickness of the first bit line spacer 621 along the first direction X.

Subsequently, referring to FIG. 16, the first material layer 150a may be patterned. That is, at least a portion of the first material layer 150a disposed in the direct contact trench DCT may be removed by performing a photo and etching process. The trench spacer 650 and the first material layer 150a may be patterned using the first bit line spacer 621 as an etching mask. Through this patterning process, the direct contact DC disposed in the direct contact trench DCT may be formed. The direct contact DC may be substantially disposed at a central portion of the direct contact trench DCT.

The bit line structure BLS may be disposed on the direct contact DC. That is, the first conductive layer 151 and the second conductive layer 153 of the bit line BL may be sequentially disposed on the direct contact DC, and the bit line capping layer 155 may be disposed on the second conductive layer 153.

In addition, after forming the first bit line spacer 621 on the side surface of the bit line structure BLS, as the first material layer 150a is patterned, the first bit line spacer 621 may be disposed on the upper surface of the direct contact DC.

That is, as the first bit line spacer 621 disposed on the side surface of the bit line BL serves as a mask in the process step of patterning the first material layer 150a, it may overlap the first bit line spacer 621 in the third direction Z, and the first material layer 150a disposed below the first bit line spacer 621 may not be etched.

Accordingly, the width of the direct contact DC of the first material layer 150a along the first direction X may be different from the width of the bit line BL along the first direction X. For example, the width of the direct contact DC along the first direction X may be greater than the width of the bit line BL along the first direction X. In addition, the side surface of the first bit line spacer 621 may be aligned with the side surface of the direct contact DC at substantially the same boundary in the third direction Z.

In the step of patterning the first material layer 150a disposed within the direct contact trench DCT, the trench spacer 650 conformally formed along the sidewall of the direct contact trench DCT may be removed together.

As the trench spacer 650 including the same material as the first material layer 150a is formed in the direct contact trench DCT, in the process step of forming the direct contact DC by patterning the first material layer 150a, the first material layer 150a disposed within the direct contact trench DCT may be smoothly etched.

That is, by forming the trench spacer 650 including the same material as the first material layer 150a along the side surfaces of the insulating layer 640 and the device isolation layer 112, which include a material different from that of the first material layer 150a, etching defects may be prevented from occurring at interfaces between the first material layer 150a and the insulating layer 640 and between the first material layer 150a and the device isolation layer 112.

In addition, in the step of patterning the first material layer 150a disposed in the direct contact trench DCT, as a portion of the third insulating layer 646 is removed together, the upper surface of the second insulating layer 644 disposed under the third insulating layer 646 may be exposed to the outside.

That is, as the first bit line spacer 621 disposed on the upper surface of the third insulating layer 646 serves as a mask, it may overlap the third insulating layer 646 in the third direction Z, and the third insulating layer 646 disposed under the first bit line spacer 621 may not be etched.

Accordingly, the third insulating layer 646 non-overlapping the first bit line spacer 621 in the third direction Z may be etched, and the upper surface of the second insulating layer 644 disposed under the third insulating layer 646 may be exposed. As the second insulating layer 644 includes a material having an etch selectivity different from that of the third insulating layer 646, the second insulating layer 644 may serve as an etch stop film.

The fabricating method of the semiconductor device according to some example embodiments may further include a cleaning process step for removing residue remaining in the direct contact trench DCT after patterning the first material layer 150a to form the direct contact DC.

As described above, since the first bit line spacer 621 is formed on the side surface of the bit line BL and then the first material layer 150a is patterned to form the direct contact DC, in the cleaning process step for removing residue remaining in the direct contact trench DCT, the side surface of the bit line BL including the conductive material may not be exposed by the first bit line spacer 621, but it may be covered by the first bit line spacer 621.

As described above, in the semiconductor device according to some example embodiments, the bit line BL may include a metallic material different from that of the direct contact DC. The bit line BL may include a plurality of layers, and at least one of the plurality of layers configuring the bit line BL may include a metallic material different from that of the direct contact DC. For example, the bit line BL may include the first conductive layer 151 and the second conductive layer 153, and at least one of the first conductive layer 151 or the second conductive layer 153 may include a metallic material different from the direct contact DC.

Accordingly, when the side surface of the bit line BL is exposed in the cleaning process of removing the residues in the direct contact trench DCT, galvanic corrosion may occur due to a potential difference the direct contact DC and the bit line BL including different conductive materials.

In the semiconductor device according to some example embodiments, since the side surface of the bit line BL is covered by the first bit line spacer 621 in the step of performing the cleaning process of removing the residues in the direct contact trench DCT, it is possible to prevent the bit line BL from being damaged by galvanic corrosion by blocking exposure of the bit line BL to the cleaning material.

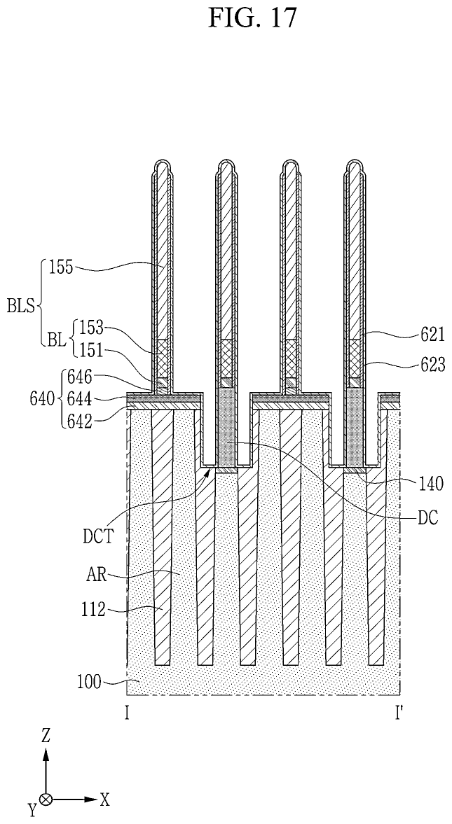

Subsequently, referring to FIG. 17, the second bit line spacer 623 may be formed using an insulating material on the bit line structure BLS. For example, the insulating material may include a silicon nitride. However, the insulating material is not limited thereto, and may be variously changed.

The second bit line spacer 623 may be conformally formed on the bit line structure BLS. The second bit line spacer 623 may cover the side surfaces of the bit line structure BLS and the direct contact DC. The second bit line spacer 623 may cover the side surface of the third insulating layer 646, the upper surface and the side surface of the second insulating layer 644, and the side surface of the first insulating layer 642. In addition, the second bit line spacer 623 may cover the bottom surface and the sidewall of the direct contact trench DCT.

In some example embodiments, a thickness of the second bit line spacer 623 may be thinner than a thickness of the first bit line spacer 621. Here, the thickness of the first bit line spacer 621 and the thickness of the second bit line spacer 623 may mean a thickness along the first direction X. However, the thickness relationship between the first bit line spacer 621 and the second bit line spacer 623 is not limited thereto, and may be variously changed.

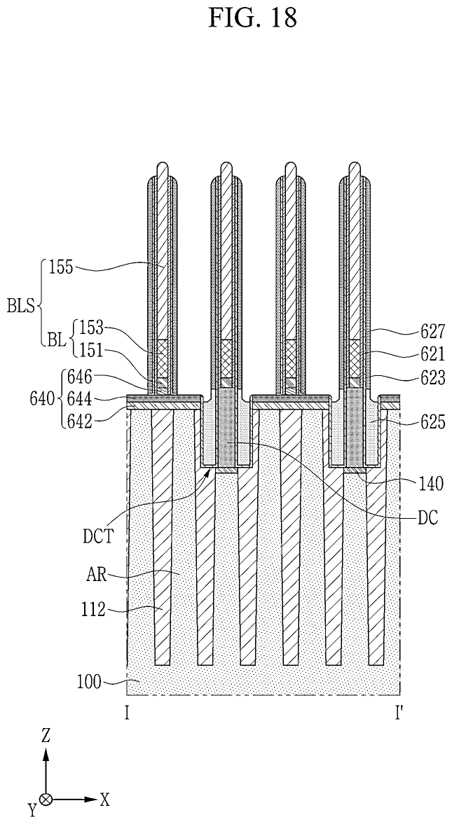

Subsequently, referring to FIG. 18, the third bit line spacer 625 disposed within the direct contact trench DCT may be formed, and the fourth bit line spacer 627 may be formed on the second bit line spacer 623 and the third bit line spacer 625.

Specifically, the third bit line spacer 625 may be formed on the second bit line spacer 623 using an insulating material. For example, the insulating material may include a silicon nitride. However, the insulating material is not limited thereto, and may be variously changed.

The third bit line spacer 625 may be conformally formed on the first bit line spacer 621. The third bit line spacer 625 may be formed to fill the direct contact trench DCT. A thickness of the third bit line spacer 625 may be thicker than that of the first bit line spacer 621 and that of the second bit line spacer 623.

Here, the thickness of the first bit line spacer 621, the thickness of the second bit line spacer 623, and the thickness of the third bit line spacer 625 may mean a thickness along the first direction X. However, the relationship between the thickness of the first bit line spacer 621, the thickness of the second bit line spacer 623, and the thickness of the third bit line spacer 625 is not limited thereto, and may be variously changed.

Next, the third bit line spacer 625 may be patterned to leave a portion of the third bit line spacer 625 disposed in the direct contact trench DCT, and the remaining portion thereof may be removed. A portion of the third bit line spacer 625 covering the bit line structure BLS may be removed.

Subsequently, the fourth bit line spacer 627 may be formed on the second bit line spacer 623 and the third bit line spacer 625 by using an insulating material. For example, the insulating material may include a silicon oxide. However, the insulating material is not limited thereto, and may be variously changed.

The fourth bit line spacer 627 may be conformally formed on the second bit line spacer 623 and the third bit line spacer 625. A thickness of the fourth bit line spacer 627 may be thicker than that of the first bit line spacer 621 and that of the second bit line spacer 623, and may be thinner than that of the third bit line spacer 625.

Here, the thickness of the first bit line spacer 621, the thickness of the second bit line spacer 623, the thickness of the third bit line spacer 625, and the thickness of the fourth bit line spacer 627 may mean a thickness along the first direction X. However, the relationship between the thickness of the first bit line spacer 621, the thickness of the second bit line spacer 623, the thickness of the third bit line spacer 625, and the thickness of the fourth bit line spacer 627 is not limited thereto, and may be variously changed.

Subsequently, the second bit line spacer 623 and the fourth bit line spacer 627 may be patterned. That is, the second bit line spacer 623 and the fourth bit line spacer 627 disposed between the bit line structures BLS, and the second bit line spacer 623 and the fourth bit line spacer 627 disposed on the upper surface of the bit line structure BLS may be partially removed.

As the second bit line spacer 623 and the fourth bit line spacer 627 are partially removed, the upper surface of the bit line structure BLS may be exposed. That is, the upper surface and the side surface of the bit line capping layer 155 may be partially exposed.

In addition, as the second bit line spacer 623 and the fourth bit line spacer 627 are partially removed, the upper surface of the second insulating layer 644 and the upper surface of the third bit line spacer 625 may be partially exposed. That is, the upper surface of the second insulating layer 644 and the upper surface of the third bit line spacer 625 disposed between the bit line structures BLS may be partially exposed.

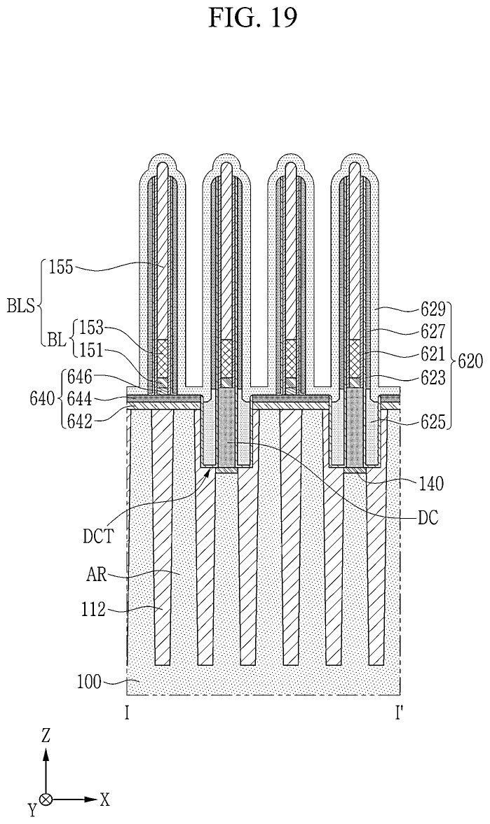

Subsequently, referring to FIG. 19, the fifth bit line spacer 629 may be formed on the fourth bit line spacer 627 by using an insulating material. For example, the insulating material may include a silicon nitride. However, the insulating material is not limited thereto, and may be variously changed.

The fifth bit line spacer 629 may be conformally formed on the upper surface of the bit line structure BLS, the fourth bit line spacer 627, and the upper surface of the second insulating layer 644. The first bit line spacer 621, the second bit line spacer 623, the third bit line spacer 625, the fourth bit line spacer 627, and the fifth bit line spacer 629 may configure the bit line spacer structure 620.

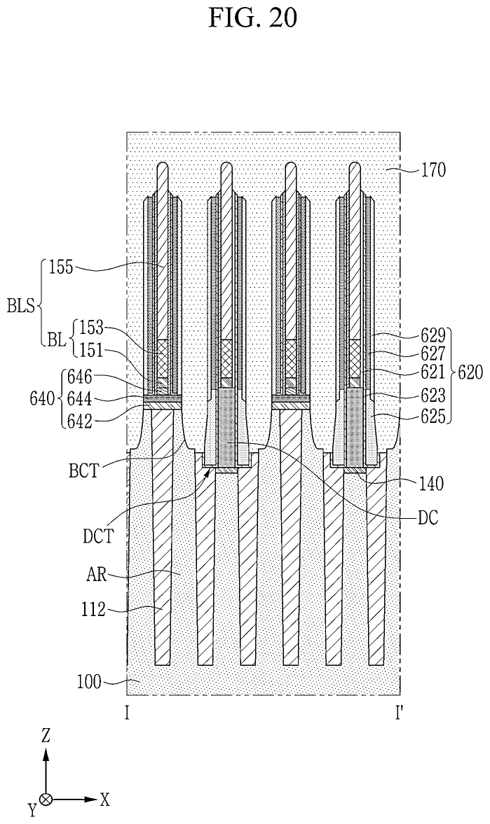

Subsequently, referring to FIG. 20, the fifth bit line spacer 629 may be patterned. By removing a portion of the fifth bit line spacer 629, the upper surface of the bit line structure BLS may be exposed. That is, the upper and side surfaces of the bit line structure BLS may be partially exposed. In addition, by removing a portion of the fifth bit line spacer 629, the upper surface of the second insulating layer 644 disposed between the bit line structures BLS may be exposed.

Accordingly, the fifth bit line spacer 629 may be disposed on the side surface of the bit line structure BLS, and may come into contact with the fourth bit line spacer 627 and the third bit line spacer 625. In addition, the fifth bit line spacer 629 may contact the upper surface of the second insulating layer 644.

A thickness of the fifth bit line spacer 629 may be thicker than that of the first bit line spacer 621 and that of the second bit line spacer 623, and may be thinner than that of the third bit line spacer 625 and that of the fourth bit line spacer 627. The thickness of the fifth bit line spacer 629 may be reduced during the patterning of the fifth bit line spacer 629.

Here, the thickness of the first bit line spacer 621, the thickness of the second bit line spacer 623, the thickness of the third bit line spacer 625, the thickness of the fourth bit line spacer 627, and the thickness of the fifth bit line spacer 629 may mean a thickness along the first direction X. However, the relationship between the thickness of the first bit line spacer 621, the thickness of the second bit line spacer 623, the thickness of the third bit line spacer 625, the thickness of the fourth bit line spacer 627, and the thickness of the fifth bit line spacer 629 is not limited thereto, and may be variously changed.

Subsequently, an etching process may be performed to remove at least a portion of the active region AR to form the buried contact trench BCT. When at least a portion of the active region AR is removed, at least some of the device isolation layer 112, the second bit line spacer 623, the third bit line spacer 625, the second insulating layer 644, and the third insulating layer 646 disposed around the active region AR may be removed together.

In addition, at least some of the first bit line spacer 621, the second bit line spacer 623, the fourth bit line spacer 627, and the fifth bit line spacer 629 disposed around the bit line capping layer 155 may be removed together.

Subsequently, the conductive material layer 170 may be formed on the bit line structure BLS. The conductive material layer 170 may be formed between the bit line structures BLS. The buried contact trench BCT may be filled with the conductive material layer 170.

Accordingly, the conductive material layer 170 may contact the active region AR. The conductive material layer 170 may include a conductive material. For example, the conductive material layer 170 may include polysilicon doped with impurities, but is not limited thereto.

As shown in FIG. 2, the buried contact BC may be formed by patterning the conductive material layer 170. The buried contact BC may be electrically connected to the active region AR.

Subsequently, the landing pad LP connected to the buried contact BC may be formed, and the insulating pattern 660 isolating the landing pads LP may be formed. Although not illustrated, a capacitor structure may be further formed on the landing pad LP. The capacitor structure may be electrically connected to the active region AR through the landing pad LP and the buried contact BC.

While some example embodiments of the present inventive concepts have been described in connection with what is presently considered to be practical embodiments, it is to be understood that the inventive concepts are not limited to such example embodiments, but, on the contrary, the inventive concepts are intended to cover various modifications and equivalent arrangements included within the spirit and scope of the appended claims.

What is claimed is:

1. A semiconductor device, comprising:
a substrate including an active region defined by a device isolation layer;
a word line that crosses and overlaps the active region;
a bit line crossing the active region in a direction different from the word line;
a direct contact that connects the active region and the bit line, the direct contact including a metallic material;
a buried contact connected to the active region; and
a bit line spacer between the bit line and the buried contact,
wherein a width of the direct contact is different from a width of the bit line, and
wherein the bit line spacer is on an upper surface of the direct contact.

2. The semiconductor device of claim 1, wherein
the width of the direct contact is greater than the width of the bit line.

3. The semiconductor device of claim 2, wherein
a side surface of the direct contact protrudes outward from a side surface of the bit line.

4. The semiconductor device of claim 3, wherein
a side surface of the bit line spacer is coplanar with the side surface of the direct contact.

5. The semiconductor device of claim 3, wherein
the side surface of the direct contact protrudes outward from the side surface of the bit line spacer.

6. The semiconductor device of claim 1, wherein
the bit line spacer directly contacts a side surface of the bit line and the upper surface of the direct contact.

7. The semiconductor device of claim 6, wherein
the bit line spacer covers the side surface of the bit line, and
the bit line spacer covers at least a portion of the upper surface of the direct contact that does not overlap the bit line in a vertical direction.

8. The semiconductor device of claim 1, wherein
a width of the upper surface of the direct contact is greater than a width of a lower surface of the direct contact.

9. The semiconductor device of claim 8, wherein
the width of the lower surface of the direct contact is greater than the width of the bit line.

10. The semiconductor device of claim 1, further comprising:
a silicide layer between an upper surface of the active region and the direct contact,
a width of the silicide layer is greater than the width of the direct contact.

11. The semiconductor device of claim 1, wherein
a thickness of the bit line spacer is about 0.5 nm to 1 nm.

12. The semiconductor device of claim 1, wherein
the bit line spacer includes at least one of SiO₂, SiN, SiOCN, SiOC, SiBN, SiBCN, or SiBCON.

13. A semiconductor device, comprising:
a substrate including an active region defined by a device isolation layer;
a word line that crosses and overlaps the active region;
a bit line crossing the active region in a direction different from the word line;
a direct contact that connects the active region and the bit line, the direct contact including a metallic material;
a silicide layer between the active region and the direct contact;
a buried contact connected to the active region;
a first bit line spacer on an upper surface of the direct contact;
a second bit line spacer between the first bit line spacer and the buried contact; and
a landing pad connected to the active region through the buried contact,
wherein a width of the direct contact is greater than a width of the bit line.

14. The semiconductor device of claim 13, wherein
a width of the first bit line spacer is equal to a difference between the width of the direct contact and the width of the bit line.

15. The semiconductor device of claim 14, wherein
the first bit line spacer covers both a side surface of the bit line and the upper surface of the direct contact, and
the second bit line spacer covers both a side surface of the first bit line spacer and a side surface of the direct contact.

16. The semiconductor device of claim 15, wherein
the first bit line spacer includes at least one of SiO₂, SiN, SiOCN, SiOC, SiBN, SiBCN, or SiBCON.

17. The semiconductor device of claim 16, further comprising
a third bit line spacer between the second bit line spacer and the buried contact; and
a fourth bit line spacer between the second bit line spacer and the third bit line spacer,
wherein the first bit line spacer includes at least one of SiOCN, SiOC, SiBN, SiBCN, or SiBCON;
wherein the second bit line spacer and the third bit line spacer each include SiN; and
wherein the fourth bit line spacer includes SiO₂.

18. A fabricating method of a semiconductor device, the fabricating method comprising:
forming a device isolation layer in a substrate to define an active region;
forming an insulating layer on the substrate and then patterning the insulating layer to form a direct contact trench to expose an upper surface of the active region;
forming a trench spacer in the direct contact trench on the exposed upper surface of the active region;
forming a first material layer including a metallic material in the direct contact trench;
sequentially stacking a second material layer, a third material layer, and a fourth material layer on the insulating layer and the first material layer;
forming a bit line based on patterning at least some of the second material layer, the third material layer, and the fourth material layer;
forming a first bit line spacer to cover a side surface of the bit line;
patterning the trench spacer and the first material layer using the first bit line spacer as an etching mask,
forming a direct contact connected to the active region and the bit line;
forming a second bit line spacer covering the first bit line spacer and the direct contact;
forming a buried contact connected to the active region; and
forming a landing pad connected to the active region through the buried contact.

19. The fabricating method of the semiconductor device of claim 18, wherein
based on patterning the first material layer using the first bit line spacer as the etching mask,
a side surface of the first bit line spacer is coplanar with a side surface of the direct contact, and
the direct contact has a width greater than a width of the bit line.

20. The fabricating method of the semiconductor device of claim 18, wherein
the first bit line spacer includes at least one of SiO₂, SiN, SiOCN, SiOC, SiBN, SiBCN, or SiBCON; and
a thickness of the first bit line spacer is about 0.5 nm to 1 nm.
